(19) United States
(12) Patent Application Publication
(10) Pub. No.: US 2026/0191075 A1
(43) Pub. Date: Jul. 2, 2026

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Ilgeun Jung, Suwon-si (KR); Sungjin Kim, Suwon-si (KR); Yongjin Jeon, Suwon-si (KR)

(21) Appl. No.: 19/431,715

(22) Filed: Dec. 23, 2025

(30) Foreign Application Priority Data
Dec. 26, 2024 (KR) 10-2024-0197382

(51) Int. Cl. H10W 72/20; H10D 80/30; H10W 40/20; H10W 40/22; H10W 40/25; H10W 90/00; H10W 90/20

(52) U.S. Cl. CPC H10W 72/265; H10W 40/22; H10W 40/233; H10W 40/258; H10W 72/267; H10W 90/297; H10W 90/722; H10D 80/30

(57) ABSTRACT

A semiconductor chip includes a semiconductor substrate including a main chip region and a residual scribe lane region surrounding the main chip region, a stacked insulating structure arranged on the semiconductor substrate, a plurality of bump pads opened by a passivation layer on the stacked insulating structure in the main chip region, a heat transfer pad opened by the passivation layer in the residual scribe lane region, and a through structure passing through the stacked insulating structure and the semiconductor substrate in a vertical direction from a bottom surface of the heat transfer pad to a lowermost surface of the semiconductor substrate in the residual scribe lane region. The through structure completely surrounds the main chip region when viewed in a plan view and comprises one body when viewed in a cross-sectional view.

### CROSS-REFERENCE TO RELATED APPLICATION

This application claims priority under 35 U.S.C. § 119 to Korean Patent Application No. 10-2024-0197382, filed on Dec. 26, 2024, in the Korean Intellectual Property Office, the entirety of which is incorporated by reference herein.

### BACKGROUND

In general, semiconductor chips are made through a die sawing process of cutting a semiconductor substrate on which a semiconductor device is formed. During the die sawing process, a sawing blade or laser saw cuts the semiconductor substrate along a scribe lane region, resulting in the semiconductor chips being physically separated from each other. As demands for larger capacity and higher integration of semiconductor devices increase, the area occupied by the scribe lane region on the semiconductor substrate is decreasing, and the risk of damage to the semiconductor devices due to stress applied to the semiconductor chips during the die sawing process is increasing.

### SUMMARY

Some aspects of the present disclosure provide semiconductor chips having a crack propagation-preventing through structure to prevent or reduce the propagation of cracks that may occur during a die sawing process of cutting a semiconductor substrate. The present disclosure also provides semiconductor packages including the semiconductor chips.

Other advantageous aspects of the present disclosure will be clearly understood by those skilled in the art from the following description.

According to some implementations of the present disclosure, there is provided a semiconductor chip including a semiconductor substrate including a main chip region and a residual scribe lane region surrounding the main chip region, a stacked insulating structure arranged on the semiconductor substrate, a plurality of bump pads opened by a passivation layer on the stacked insulating structure in the main chip region, a heat transfer pad opened by the passivation layer in the residual scribe lane region, and a through structure passing through the stacked insulating structure and the semiconductor substrate in a vertical direction from a bottom surface of the heat transfer pad to a lowermost surface of the semiconductor substrate in the residual scribe lane region. The through structure completely surrounds the main chip region when viewed in a plan view and includes one body when viewed in a cross-sectional view.

According to some implementations of the present disclosure, there is provided a semiconductor chip including a semiconductor substrate, a main chip region in which a plurality of transistors are arranged on the semiconductor substrate, a residual scribe lane region surrounding the main chip region on the semiconductor substrate, a through structure extending through the semiconductor substrate in a vertical direction in the residual scribe lane region, and a heat transfer pad arranged on the through structure in the residual scribe lane region. The through structure protects the main chip region from cracks and dissipates heat generated by the main chip region.

According to some implementations of the present disclosure, there is provided a semiconductor package including a package substrate, a semiconductor chip stack mounted on the package substrate and including a plurality of semiconductor chips, and a molding member surrounding the semiconductor chip stack. Each of the plurality of semiconductor chips includes a semiconductor substrate including a main chip region and a residual scribe lane region surrounding the main chip region, a stacked insulating structure arranged on the semiconductor substrate, a plurality of bump pads opened by a passivation layer on the stacked insulating structure in the main chip region, a heat transfer pad opened by the passivation layer in the residual scribe lane region, and a through structure passing through the stacked insulating structure and the semiconductor substrate in a vertical direction from a bottom surface of the heat transfer pad to a lowermost surface of the semiconductor substrate in the residual scribe lane region. In the semiconductor chip stack, the plurality of semiconductor chips are connected to one another and stacked by the plurality of bump pads and a plurality of solder bumps arranged on the heat transfer pad.

### BRIEF DESCRIPTION OF THE DRAWINGS

FIG. 1 is a schematic plan view illustrating an example of a wafer including a semiconductor chip;

FIG. 2 is a schematic plan view of an example of a semiconductor chip;

FIG. 3 is a cross-sectional view taken along line A-A′ of FIG. 2;

FIG. 4 is an enlarged cross-sectional view of the BB portion of FIG. 3;

FIG. 5 is a schematic cross-sectional view illustrating an example of a semiconductor package including first to fourth semiconductor chips;

FIGS. 6 to 8 are plan views illustrating examples of semiconductor chips;

FIGS. 9 to 15 are cross-sectional views illustrating an example of a method of manufacturing a semiconductor chip; and

FIG. 16 is a block diagram illustrating an example of a system of a semiconductor package.

### DETAILED DESCRIPTION

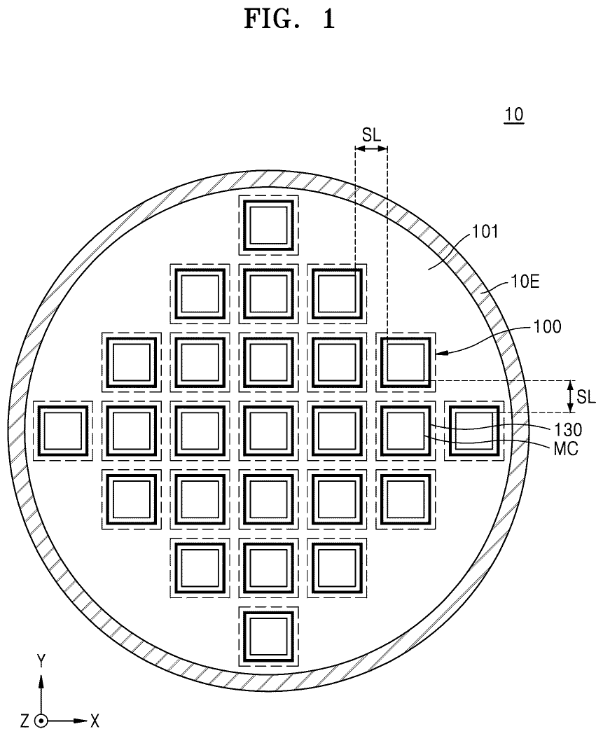

FIG. 1 is a schematic plan view illustrating an example of a wafer including a semiconductor chip.

Referring to FIG. 1, a wafer 10 includes a plurality of main chip regions MC and a scribe lane region SL defined between the plurality of main chip regions MC.

The wafer 10 has an edge 10E. In addition, the wafer 10 has a top surface (or an active surface) on which the plurality of main chip regions MC are formed and a bottom surface (or an inactive surface) facing the top surface. The bottom surface of the wafer 10 may be a polished surface on which a polishing process is performed to reduce the thickness of the wafer 10. The polishing process may include a grinding process.

The plurality of main chip regions MC may be arranged on the top surface of the wafer 10, and the scribe lane region SL may be defined between the plurality of main chip regions MC. The scribe lane region SL may extend in a first horizontal direction X and a second horizontal direction Y perpendicular to the first horizontal direction X. The scribe lane region SL may be in the form of a straight lane having a constant width, or multiple straight lanes having straight widths. For example, the plurality of main chip regions MC may be surrounded by the scribe lane region SL and may be apart from one another.

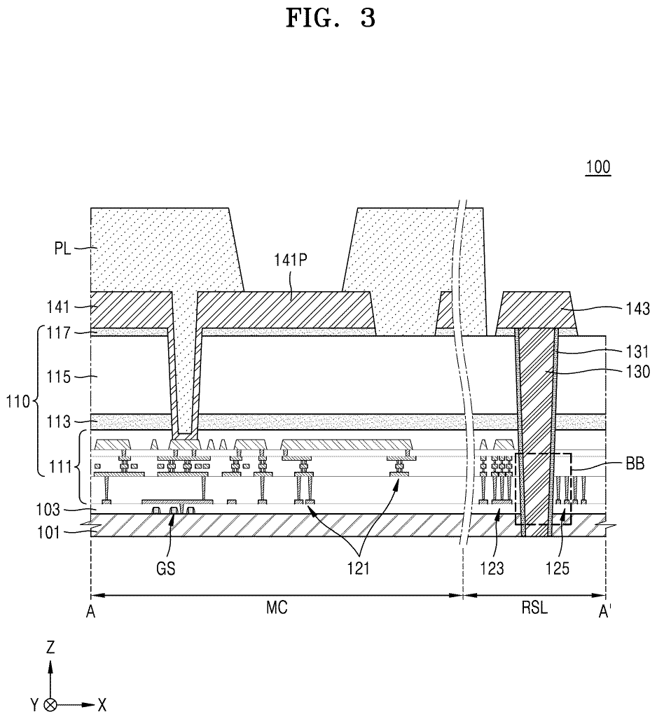

The semiconductor chip 100 may include one main chip region MC and a residual scribe lane region RSL (refer to FIG. 3) surrounding the main chip region MC.

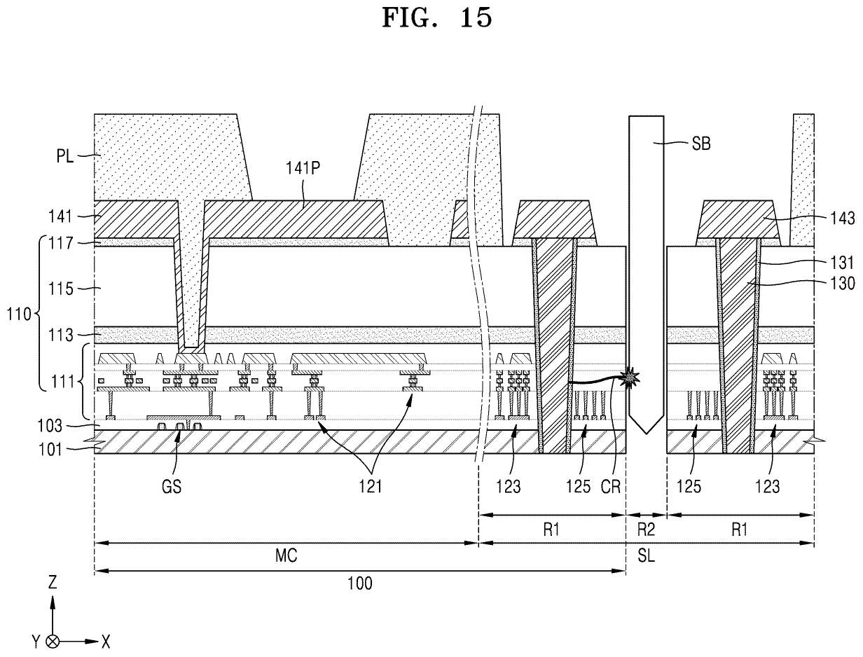

The semiconductor chips 100 may be physically separated from one another by performing a die sawing process along the scribe lane region SL. As the wafer 10 and various types of material films formed on the wafer 10 are cut by the die sawing process using a sawing blade SB (refer to FIG. 15) or laser sawing, the wafer 10 may be cut into a plurality of semiconductor chips 100.

In the current specification, for convenience of explanation, the die sawing process using the sawing blade SB is described. However, the description herein may be substantially equally applied to a die sawing process using laser sawing or other suitable die sawing technologies.

For example, as labeled in FIG. 15, the scribe lane region SL may be divided into a first region R1 surrounding the edge of the main chip region MC at a portion adjacent to the main chip region MC and a second region R2 surrounding the first region R1. For example, the second region R2 may be spaced apart from the main chip region MC with the first region R1 therebetween. Here, the first region R1 is a portion through which the sawing blade SB (or laser, hereinafter not repeatedly mentioned but understood to be within the scope of the description) does not pass during the die sawing process, and the first region R1 may provide a margin of the die sawing process. The second region R2 may be cut by the sawing blade SB passing through the second region R2 during the die sawing process. For example, the sawing blade SB may separate the semiconductor chips 100 from one another along the second region R2. Here, the first region R1 may be referred to as the residual scribe lane region RSL (refer to FIG. 3).

Recently, as demands for larger capacity and higher integration of semiconductor devices increase, the area occupied by the scribe lane region SL on the wafer 10 is decreasing. Accordingly, the risk of damage to the semiconductor device arranged in the main chip region MC increases due to mechanical stress applied to the semiconductor chip 100 in the die sawing process. In addition, a structure capable of effectively dissipating heat generated by the main chip region MC is required.

Accordingly, the present disclosure provides structures that can increase reliability and productivity of the semiconductor chip 100 in the context of die sawing. For example, according to some implementations of the present disclosure, a through structure 130 (refer to FIG. 3) is formed in the residual scribe lane region RSL to prevent or reduce propagation of cracks that may occur in the die sawing process, and a heat transfer pad 143 (refer to FIG. 3) is formed on the through structure 130 to effectively dissipate heat.

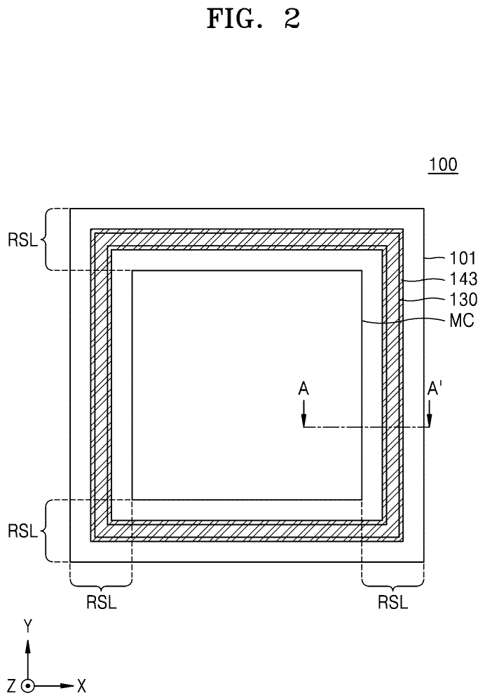

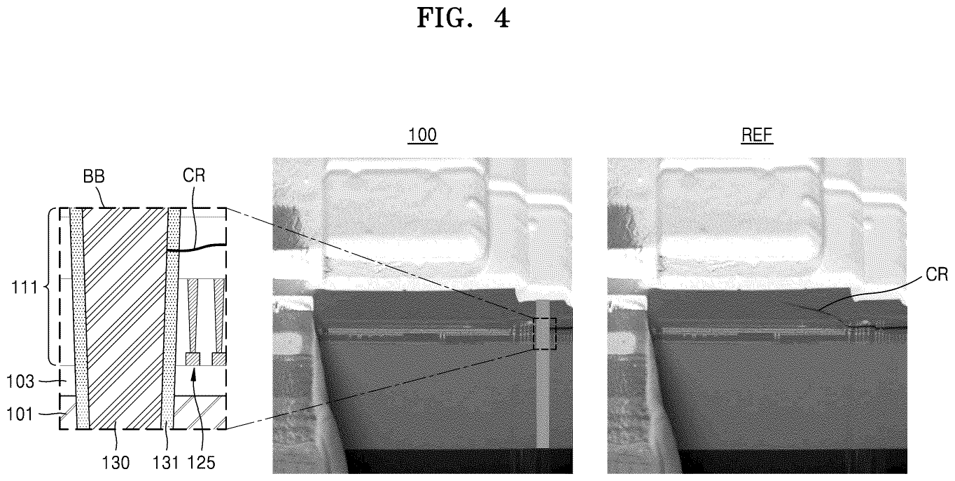

FIG. 2 is a schematic plan view of an example of a semiconductor chip. FIG. 3 is a cross-sectional view taken along line A-A′ of FIG. 2. FIG. 4 is an enlarged cross-sectional view of the BB portion of FIG. 3.

Referring to FIGS. 2 to 4 together, the semiconductor chip 100 includes the main chip region MC and the residual scribe lane region RSL surrounding the main chip region MC and having the through structure 130 arranged therein.

A semiconductor substrate 101 may include a semiconductor material, for example, silicon (Si). As another example, the semiconductor substrate 101 may include a semiconductor element material such as germanium (Ge), or a compound semiconductor material such as silicon carbide (SiC), gallium arsenide (GaAs), indium arsenide (InAs), or indium phosphide (InP). In some implementations, the semiconductor substrate 101 may have a silicon-on-insulator (SOI) structure. The semiconductor substrate 101 may include a conductive region, for example, an impurity-doped well or an impurity-doped structure. In some implementations, the semiconductor substrate 101 is the wafer 10.

A semiconductor device layer 103 may be arranged on the semiconductor substrate 101. A semiconductor device may be arranged in the main chip region MC of the semiconductor device layer 103. The semiconductor device may include a memory device, a logic device, and/or another type of suitable device. For example, the semiconductor device may include various types of individual devices. The individual devices may include various microelectronic devices, for example, a metal-oxide-semiconductor field-effect-transistor (MOSFET) such as a CMOS transistor, an image sensor such as a CMOS imaging sensor (CIS), system large scale integration (LSI), a micro-electro-mechanical system (MEMS), an active device, and a passive device.

The main chip region MC of the semiconductor chip 100 will be described in detail as follows. The semiconductor device may include a gate structure GS. Although the gate structure GS is illustrated as a plannar type in the drawing, the gate structure configuration is not limited thereto. The semiconductor chip 100 may include a plurality of gate structures GS and a wiring structure 121 in the main chip region MC, and may include a stacked insulating structure 110 surrounding the plurality of gate structures GS and the wiring structure 121 on the semiconductor substrate 101.

The stacked insulating structure 110 may be formed by sequentially stacking a first insulating layer 111, a second insulating layer 113, a third insulating layer 115, and a fourth insulating layer 117. The first insulating layer 111 may directly surround the plurality of gate structures GS and the wiring structure 121 on the semiconductor substrate 101, and the second insulating layer 113, the third insulating layer 115, and the fourth insulating layer 117 may be arranged on the first insulating layer 111. Here, the first insulating layer 111 may be referred to as an interlayer dielectric layer.

The stacked insulating structure 110 may include a silicon oxide layer, a silicon nitride layer, a silicon oxynitride layer, or an insulating material having a lower dielectric constant than the silicon oxide layer. In some implementations, the stacked insulating structure 110 may include a tetraethyl orthosilicate (TEOS) layer or an ultra-low K (ULK) layer having an ultra-low dielectric constant of about 2.2 to about 2.4. The ULK layer may include, for example, a SiOC layer or a SiCOH layer.

In some implementations, the first insulating layer 111 may include a silicon oxide layer, the second insulating layer 113 may include a silicon nitride layer, the third insulating layer 115 may include a TEOS layer, and the fourth insulating layer 117 may include a silicon nitride layer. However, the layer configuration is not limited thereto.

The gate structure GS may be provided by forming a gate electrode and spacers on both sidewalls of the gate electrode, and doping impurities into the semiconductor substrate 101 positioned on both sides of the gate electrode to form a source/drain.

In the manufacturing process of forming the wiring structure 121 in the main chip region MC, a guard ring 123 and a dam structure 125 may be formed together in the residual scribe lane region RSL. For example, the guard ring 123 and the dam structure 125 may be formed by using an existing semiconductor manufacturing process without an additional manufacturing process for forming the guard ring 123 and the dam structure 125. Accordingly, the wiring structure 121, the guard ring 123, and the dam structure 125 may be formed with similar shapes and substantially the same material.

The wiring structure 121 may include a plurality of vertical vias and a plurality of metal wiring layers. Through a photolithography process and an etching process, the plurality of vertical vias and the plurality of metal wiring layers may be patterned into a desired shape to form the wiring structure 121 electrically connected to the plurality of gate structures GS. For example, some of the plurality of vertical vias may be in direct contact with the source/drain in the semiconductor substrate 101.

The wiring structure 121 may include a conductive material. For example, the wiring structure 121 may include tungsten (W), a tungsten alloy, aluminum (Al), titanium (Ti), tantalum (Ta), palladium (Pd), platinum (Pt), molybdenum (Mo), metal silicide, or a combination thereof.

A redistribution structure 141 electrically connected to the wiring structure 121 may be arranged on the main chip region MC. The redistribution structure 141 may be conformally arranged along a top surface of the stacked insulating structure 110 and a recessed internal wall of the stacked insulating structure 110. For example, the redistribution structure 141 may pass through part of the stacked insulating structure 110 and may be in contact with and be electrically connected to the wiring structure 121.

The redistribution structure 141 may include a conductive material. For example, the wiring structure 121 may include W, a tungsten alloy, Al, Ti, Ta, Pd, Pt, Mo, metal silicide, or a combination thereof.

In the semiconductor chip 100, a passivation layer PL may be arranged on the stacked insulating structure 110 and the redistribution structure 141 across the main chip region MC and the residual scribe lane region RSL. For example, the passivation layer PL may include photo imageable dielectric (PID) or photosensitive polyimide (PSPI).

A plurality of bump pads 141P exposed through openings in the passivation layer PL may be arranged in the main chip region MC, and the heat transfer pad 143 exposed by the passivation layer PL may be arranged in the residual scribe lane region RSL. The plurality of bump pads 141P may be part of the redistribution structure 141. That is, a portion of the redistribution structure 141 exposed by the passivation layer PL may be referred to as the plurality of bump pads 141P.

In the manufacturing process of forming the plurality of bump pads 141P in the main chip region MC, the heat transfer pad 143 may also be formed in the residual scribe lane region RSL. For example, the heat transfer pad 143 may be formed by using an existing semiconductor manufacturing process without an additional manufacturing process of forming the heat transfer pad 143. Accordingly, the plurality of bump pads 141P and the heat transfer pad 143 may include substantially the same material. In addition, a vertical level of the plurality of bump pads 141P may be substantially the same as a vertical level of the heat transfer pad 143.

The semiconductor chip 100 may include the through structure 130 extending from a bottom surface of the heat transfer pad 143 to the lowermost surface of the semiconductor substrate 101 through both the stacked insulating structure 110 and the semiconductor substrate 101 in the vertical direction Z in the residual scribe lane region RSL.

When viewed in a plan view, the through structure 130 may include a single continuous line or structure (e.g., a continuous, integral structure) completely surrounding the main chip region MC, for example, in a square shape. In addition, the through structure 130 may be formed as one body when viewed in a cross-sectional view. For example, in the cross-section, the through structure 130 may be an integral element. For example, the through structure 130 may be composed of a single material.

The through structure 130 may include a conductive material. For example, the through structure 130 may include copper (Cu) or a copper alloy. In some implementations, the through structure 130 may be formed integrally by an electroplating process. In addition, the through structure 130 may include a material different from that of the heat transfer pad 143.

A through insulating liner 131 may be arranged surrounding the through structure 130. Like the through structure 130, the through insulating liner 131 may extend from the bottom surface of the heat transfer pad 143 to the lowermost surface of the semiconductor substrate 101 through both the stacked insulating structure 110 and the semiconductor substrate 101 in the vertical direction Z in the residual scribe lane region RSL. The through insulating liner 131 may include an insulating material.

In the semiconductor chip 100, the heat transfer pad 143 may have a trapezoidal shape of which the horizontal width (e.g., along the X or Y direction) increases toward the semiconductor substrate 101 in the vertical direction Z, and the through structure 130 may have a tapered shape (that is, an inverted trapezoidal shape) of which the horizontal width decreases toward the lowermost surface of the semiconductor substrate 101 in the vertical direction Z. In addition, the maximum horizontal width of the heat transfer pad 143 may be greater than the maximum horizontal width of the through structure 130, and the bottom surface of the heat transfer pad 143 may be arranged to cover (e.g., overlap along a vertical direction) the entire top surface of the through structure 130.

When viewed in a plan view, the heat transfer pad 143 may include a single continuous line or other structure completely surrounding the main chip region MC, for example, in a square shape. In addition, the heat transfer pad 143 may be formed integrally when viewed in a cross-sectional view.

The heat transfer pad 143 can be electrically disconnected or electrically insulated from transistors and/or other semiconductor devices in the main chip region MC.

The sawing blade SB (refer to FIG. 15) cuts the stacked insulating structure 110 and the semiconductor substrate 101 in the vertical direction Z from the uppermost surface of the stacked insulating structure 110 to the lowermost surface of the semiconductor substrate 101. While the sawing blade SB cuts the semiconductor chip 100 along the scribe lane region SL, stress occurs due to physical friction between the sawing blade SB and the stacked insulating structure 110. Such stress may cause a crack CR to propagate into the semiconductor chip 100, and if the crack CR propagates to the main chip region MC, the reliability of the semiconductor device may be significantly reduced.

In the semiconductor chip 100, the crack CR starting at a portion at which the sawing blade SB and the stacked insulating structure 110 or the sawing blade SB and the semiconductor substrate 101 come into contact and propagating toward the main chip region MC encounters the through structure 130. For example, the crack CR starting in the scribe lane region SL may move in the first or second horizontal direction X or Y along the stacked insulating structure 110 and may disappear as stress is dispersed when the crack CR meets the through structure 130.

Accordingly, in the semiconductor chip 100, the through structure 130 (e.g., formed integrally from the uppermost surface of the stacked insulating structure 110 to the lowermost surface of the semiconductor substrate 101) may prevent the crack CR from propagating toward the main chip region MC. In FIG. 4, when comparing the semiconductor chip 100 in which the through structure 130 is formed with a reference chip REF in which the through structure 130 is not formed, it may be clearly noted that the through structure 30 inhibits propagation of the crack CR.

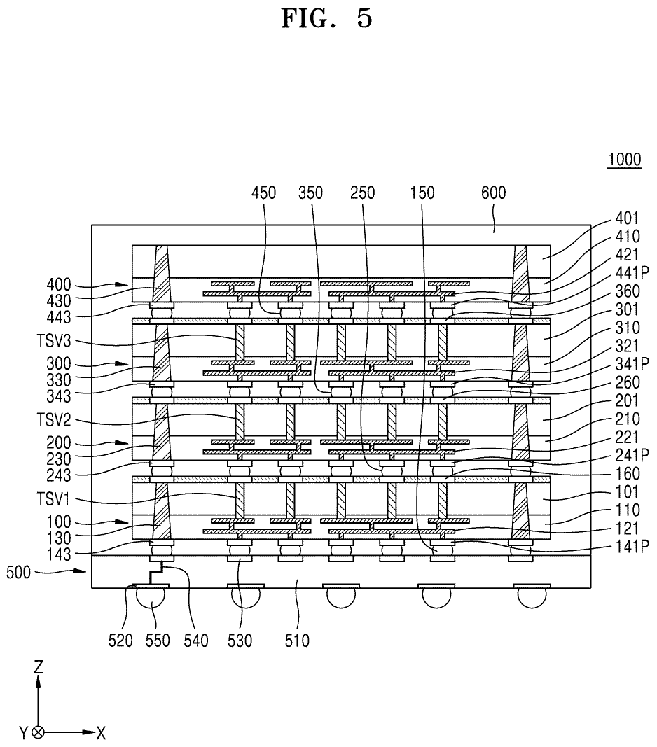

In some implementations, in the semiconductor chip 100, the heat transfer pad 143 and the through structure 130 may be used as a path through which heat generated by the main chip region MC may be effectively dissipated. Because the through structure 130 includes a single continuous line completely surrounding the main chip region MC and may include a material (e.g., copper (Cu)) with excellent thermal conductivity, the through structure 130 may have a structure advantageous in dissipating heat generated by the main chip region MC to the outside. In addition, the heat transfer pad 143 may be used as part of a vertical path for heat transfer in the semiconductor package 1000 (refer to FIG. 5) in which the plurality of semiconductor chips 100 are included in a stacked structure.

Accordingly, in some implementations, the semiconductor chip 100 provides increased reliability and productivity by including the through structure 130 that may prevent the propagation of the crack CR that may occur in the die sawing process of cutting the semiconductor substrate 101 and may effectively dissipate heat generated by the main chip region MC.

FIG. 5 is a schematic cross-sectional view illustrating an example of a semiconductor package 1000 including first to fourth semiconductor chips 100, 200, 300, and 400.

Referring to FIG. 5, the semiconductor package 1000 includes the first semiconductor chip 100, the second semiconductor chip 200, the third semiconductor chip 300, and the fourth semiconductor chip 400 stacked in a vertical direction Z on a base substrate 500.

The first to fourth semiconductor chips 100, 200, 300, and 400 as a semiconductor chip stack (e.g., respective semiconductor devices of the first to fourth semiconductor chips 100, 200, 300, and 400) may be electrically connected to one another through first to fourth connection terminals 150, 250, 350, and 450 and may be electrically connected to the base substrate 500. Each of the first to fourth semiconductor chips 100, 200, 300 and 400 may have a structure matching or substantially similar to that described for the semiconductor chip 100 (refer to FIG. 3) described above, and repeated description will be omitted.

The first to fourth semiconductor chips 100, 200, 300 and 400 may include, for example, memory chips or logic chips. For example, the first to fourth semiconductor chips 100, 200, 300, and 400 may all include the same type of memory chips. In some implementations, one or more of the first to fourth semiconductor chips 100, 200, 300, and 400 may include memory chips, and the others may include logic chips. In some implementations, the first to fourth semiconductor chips 100, 200, 300 and 400 may constitute high bandwidth memory (HBM).

Although the first to fourth semiconductor chips 100, 200, 300, and 400 are stacked in the drawing, the number of semiconductor chips stacked in the semiconductor package 1000 is not limited thereto. For example, two or more semiconductor chips may be stacked in the semiconductor package 1000.

The first semiconductor chip 100 may include a first semiconductor substrate 101, a first stacked insulating structure 110, a first wiring structure 121, a first through structure 130, a first bump pad 141P, a first heat transfer pad 143, a first connection terminal 150, a first upper pad 160, and a first through electrode TSV1.

The second semiconductor chip 200 may include a second semiconductor substrate 201, a second stacked insulating structure 210, a second wiring structure 221, a second through structure 230, a second bump pad 241P, a second heat transfer pad 243, a second connection terminal 250, a second upper pad 260, and a second through electrode TSV2.

The third semiconductor chip 300 may include a third semiconductor substrate 301, a third stacked insulating structure 310, a third wiring structure 321, a third through structure 330, a third bump pad 341P, a third heat transfer pad 343, a third connection terminal 350, a third upper pad 360, and a third through electrode TSV3.

The fourth semiconductor chip 400 may include a fourth semiconductor substrate 401, a fourth stacked insulating structure 410, a fourth wiring structure 421, a fourth through structure 430, a fourth bump pad 441P, a fourth heat transfer pad 443, and a fourth connection terminal 450. In some implementations, unlike the first to third semiconductor chips 100, 200, and 300, the fourth semiconductor chip 400 positioned at the top may not include an upper pad and a through electrode.

The second semiconductor chip 200 may be mounted on the first semiconductor chip 100, the third semiconductor chip 300 may be mounted on the second semiconductor chip 200, and the fourth semiconductor chip 400 may be mounted on the third semiconductor chip 300. An underfill may be formed under each of the first to fourth semiconductor chips 100, 200, 300 and 400.

The base substrate 500 may include a printed circuit board (PCB) or an interposer. The base substrate 500 may include a substrate body 510, and a bottom surface pad 520 and a top surface pad 530 respectively formed on a bottom surface and a top surface of the substrate body 510. In addition, internal wiring 540 may be formed in the substrate body 510.

An external connection terminal 550 may be attached to the bottom surface of the base substrate 500. The external connection terminal 550 may be attached to the bottom surface pad 520. For example, the external connection terminal 550 may include a solder ball or a solder bump. The external connection terminal 550 may electrically and thermally connect the semiconductor package 1000 to an external device (not shown).

A molding member 600 may be formed on the base substrate 500 to surround all of the first to fourth semiconductor chips 100, 200, 300 and 400. The molding member 600 may surround side surfaces of the first to fourth semiconductor chips 100, 200, 300 and 400 and a gap therebetween. For example, the molding member 600 may include an epoxy molding compound, and may have a molded underfill structure. In this case, the underfill may be omitted.

In the semiconductor package 1000, the first to fourth semiconductor chips 100, 200, 300, and 400 may be thermally connected to one another through the first to fourth through structures 130, 230, 330, and 430, the first to fourth heat transfer pads 143, 243, 343, and 443, and the first to fourth connection terminals 150, 250, 350 and 450. For example, as shown in FIG. 5, the second heat transfer pad 243 may be in contact with the second connection terminal 250, which is in contact with the first upper pad 160, which is in contact with the first through structure 130. A similar configuration applies for the other adjacent pairs of semiconductor chips.

Accordingly, in the semiconductor package 1000, heat generated by the first to fourth semiconductor chips 100, 200, 300, and 400 may be dissipated to the outside of the base substrate 500 through the first to fourth through structures 130, 230, 330, and 430, the first to fourth heat transfer pads 143, 243, 343, and 443, the first to fourth connection terminals 150, 250, 350, and 450, and the internal wiring 540.

As such, in some implementations, the semiconductor package 1000 may include the first to fourth through structures 130, 230, 330, and 430 and the first to fourth heat transfer pads 143, 243, 343, and 443 capable of effectively dissipating heat generated by the main chip region MC, thereby increasing reliability and productivity.

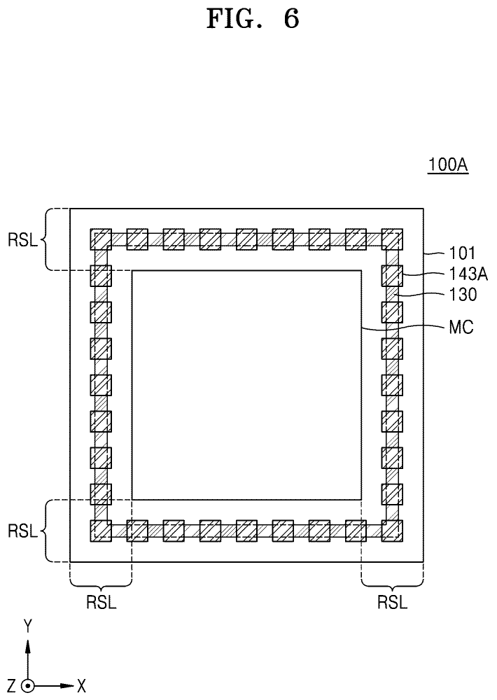

FIGS. 6 to 8 are plan views illustrating examples of semiconductor chips 100A, 100B, and 100C. Most of the components and materials of the semiconductor chips 100A, 100B, and 100C described below are substantially the same as or similar to those described above with reference to FIGS. 2 to 4. Accordingly, for convenience of explanation, differences from the semiconductor chip 100 described above will be mainly described.

Referring to FIG. 6, the semiconductor chip 100A includes a main chip region MC and a residual scribe lane region RSL surrounding the main chip region MC and having a through structure 130 arranged therein.

In the semiconductor chip 100A, a plurality of heat transfer pads 143A may be arranged in parallel to be spaced apart from one another on the through structure 130. For example, when viewed in a plan view, the plurality of heat transfer pads 143A may form a single discontinuous line, or other discontinuous shape, surrounding the main chip region MC.

For example, in the semiconductor chip 100A, the through structure 130 may include one continuous line or other structure surrounding the main chip region MC, and the plurality of heat transfer pads 143A may include one discontinuous line (for example, one dashed line) or other discontinuous structure overlapping the through structure 130 along the vertical direction Z.

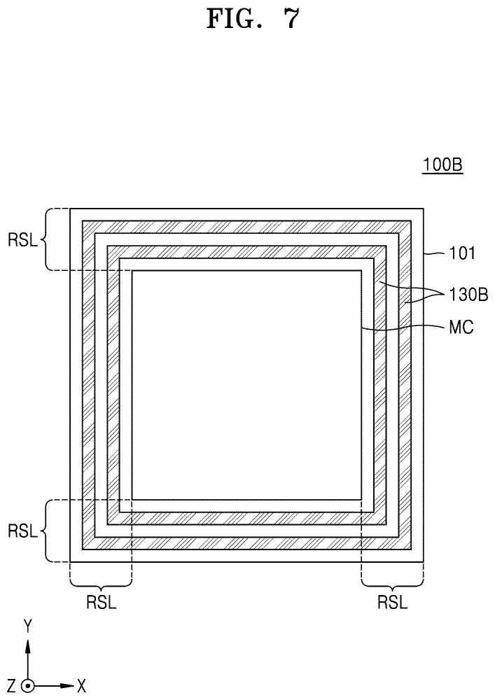

Referring to FIG. 7, the semiconductor chip 100B includes a main chip region MC and a residual scribe lane region RSL surrounding the main chip region MC and having a through structure 130B arranged therein.

In the semiconductor chip 100B, when viewed in a plan view, the through structure 130B may include a plurality of continuous lines or other structures surrounding the main chip region MC. For example, the through structure 130B may include one first continuous line completely surrounding the main chip region MC and one second continuous line completely surrounding the first continuous line. For convenience of explanation and understanding, illustration of the heat transfer pad is omitted.

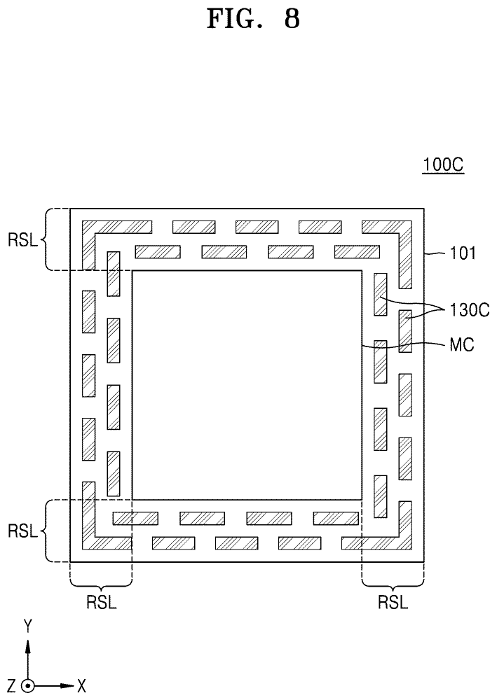

Referring to FIG. 8, the semiconductor chip 100C includes a main chip region MC and a residual scribe lane region RSL surrounding the main chip region MC and having a through structure 130C arranged therein.

In the semiconductor chip 100C, when viewed in a plan view, the through structure 130C may include a plurality of discontinuous lines or other structures surrounding the main chip region MC. For example, the through structure 130C may include one first discontinuous line (for example, one first dashed line) surrounding the main chip region MC and one second discontinuous line (for example, one second dashed line) surrounding the first discontinuous line.

In the semiconductor chip 100C, the first discontinuous line and the second discontinuous line constituting the through structure 130C may be arranged in a zigzag or offset manner to completely surround the main chip region MC. For example, the through structure 130C may be arranged such that any straight line from the main chip region MC to an outer edge of the residual scribe lane region RSL passes through at least one portion of the through structure 130, in the plan view. As such, crack propagation may be effectively inhibited. For convenience of explanation and understanding, illustration of the heat transfer pad is omitted.

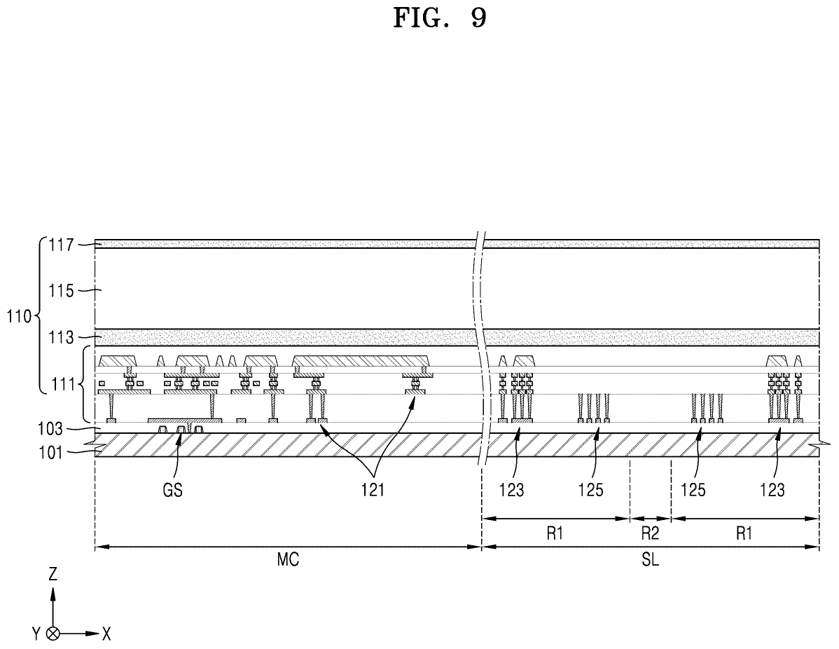

FIGS. 9 to 15 are cross-sectional views illustrating an example of a method of manufacturing a semiconductor chip.

Referring to FIG. 9, the plurality of gate structures GS and the wiring structure 121 may be formed in the main chip region MC of the semiconductor substrate 101, and the guard ring 123 and the dam structure 125 may be formed in the scribe lane region SL.

The stacked insulating structure 110 including the first insulating layer 111, the second insulating layer 113, the third insulating layer 115, and the fourth insulating layer 117 may be formed on the semiconductor substrate 101. Here, the first insulating layer 111 may surround the gate structure GS and the wiring structure 121 in the main chip region MC and may surround the guard ring 123 and the dam structure 125 in the scribe lane region SL.

The scribe lane region SL may be divided into a first region R1 surrounding the edge of the main chip region MC at a portion adjacent to the main chip region MC and a second region R2 surrounding the first region R1. That is, the second region R2 may be apart from the main chip region MC with the first region R1 therebetween.

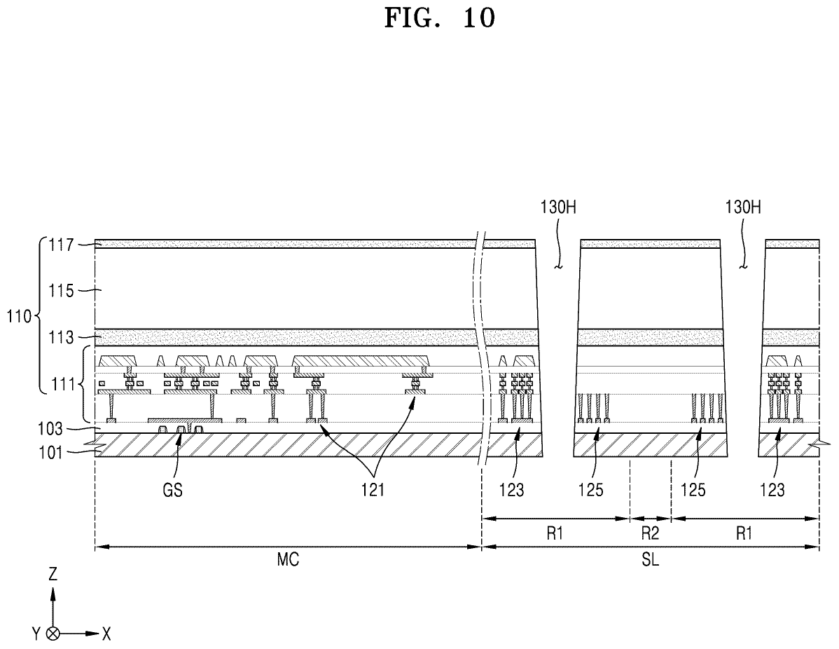

Referring to FIG. 10, a plurality of through holes 130H may be formed in the scribe lane region SL.

The plurality of through holes 130H may be formed only in the first region R1 of the scribe lane region SL. For example, the plurality of through holes 130H may not be formed in the second region R2 of the scribe lane region SL.

The plurality of through holes 130H may be formed to completely pass through the stacked insulating structure 110 and the semiconductor substrate 101 in the vertical direction Z. In some implementations, according to the characteristics of the etching process of forming the plurality of through holes 130H, each of the plurality of through holes 130H may have a tapered shape in which the horizontal width decreases toward the lowermost surface of the semiconductor substrate 101 in the vertical direction Z.

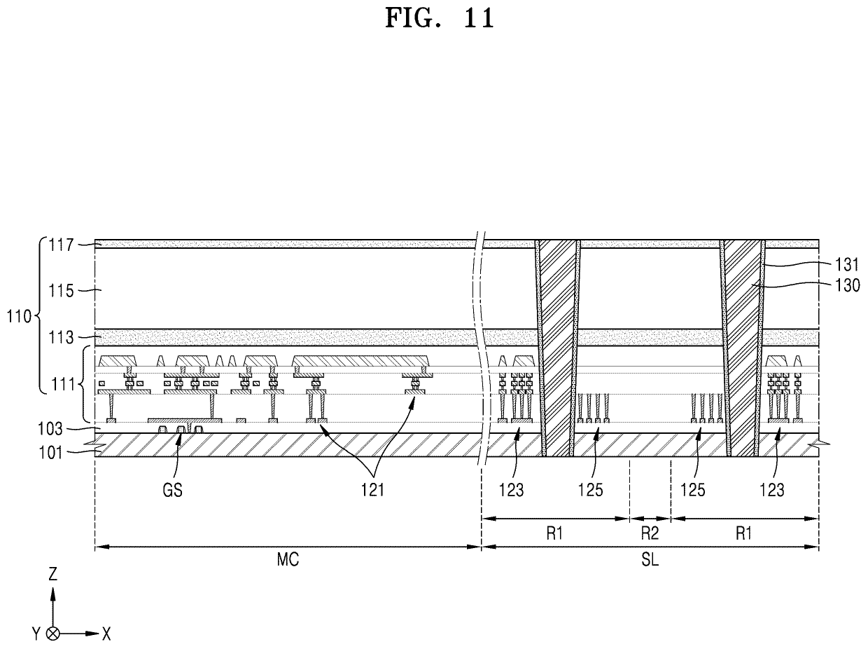

Referring to FIG. 11, a plurality of through structures 130 may be formed in the scribe lane region SL to fill a plurality of through holes 130H.

For example, first, a plurality of through insulating liners 131 may be formed conformally along internal walls of the plurality of through holes 130H, and a metal seed layer may be formed on internal walls of the plurality of through insulating liners 131. Next, the plurality of through structures 130 may be formed by an electroplating process using the metal seed layer to fill the remaining portions of the plurality of through holes 130H.

Accordingly, the uppermost surface of the stacked insulating structure 110 and the uppermost surface of the plurality of through structures 130 may have the same vertical level, and the lowermost surface of the semiconductor substrate 101 and the lowermost surface of the plurality of through structures 130 may have the same vertical level.

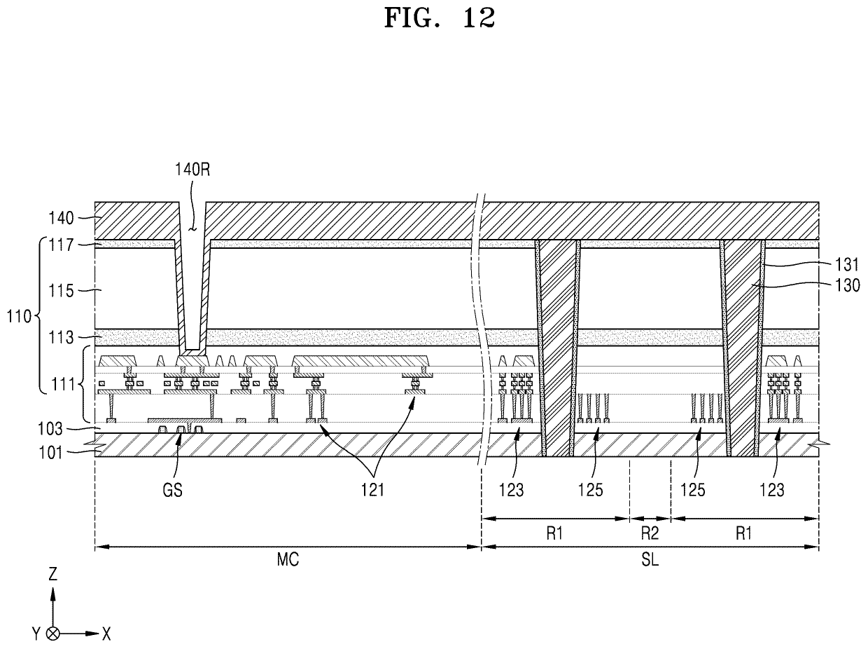

Referring to FIG. 12, a portion of the stacked insulating structure 110 may be etched in the main chip region MC to form a recess 140R exposing the wiring structure 121.

Next, a redistribution conductive layer 140 electrically connected to the wiring structure 121 may be formed in the main chip region MC. The redistribution conductive layer 140 may be conformally formed along the top surface of the stacked insulating structure 110 and an internal wall of the recess 140R formed in the stacked insulating structure 110.

Accordingly, the redistribution conductive layer 140 may pass through part of the stacked insulating structure 110 and may be in contact with and be electrically connected to the wiring structure 121.

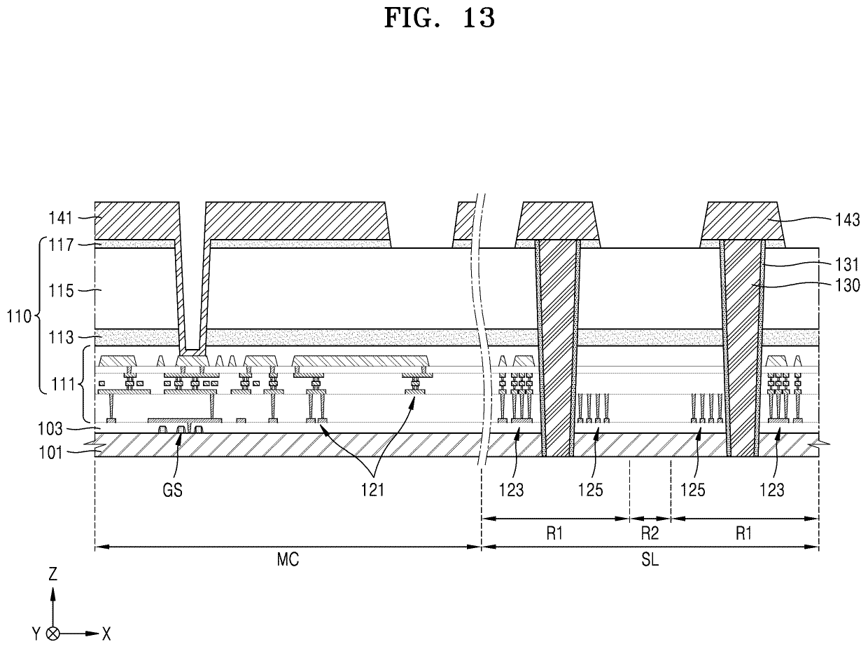

Referring to FIG. 13, a mask pattern may be formed on the redistribution conductive layer 140, and a patterning process may be performed by using the mask pattern as an etching mask. The patterning process may be performed by using a photolithography process and an etching process. According to the patterning process, the redistribution conductive layer 140 may be patterned to form the redistribution structure 141 in the main chip region MC, and to form the plurality of heat transfer pads 143 in the scribe lane region SL.

In some implementations, a portion of the fourth insulating layer 117 may also be etched by the patterning process. In some implementations, according to the characteristics of the etching process of forming the plurality of heat transfer pads 143, each of the plurality of heat transfer pads 143 may have a trapezoidal shape of which the horizontal width increases toward the semiconductor substrate 101 in the vertical direction Z.

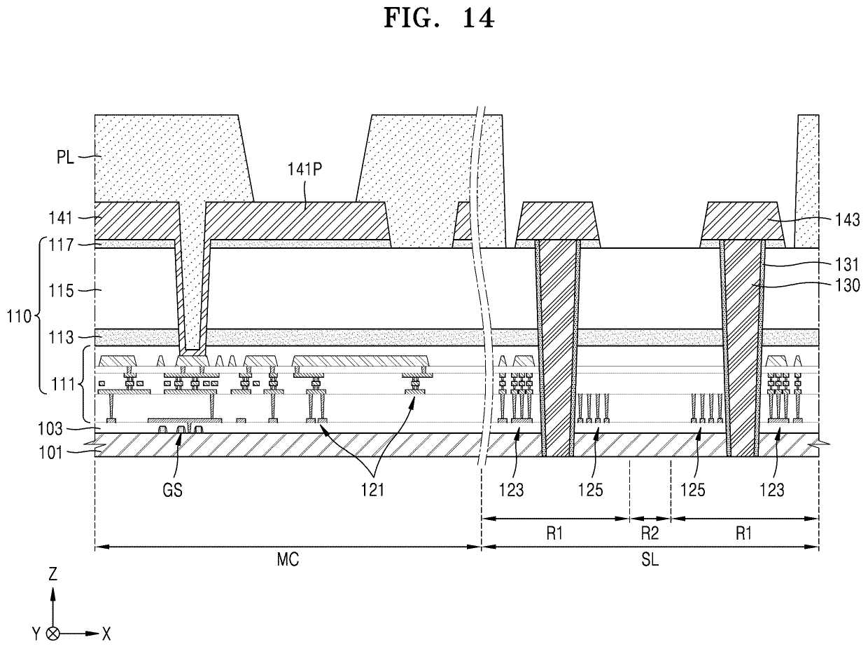

Referring to FIG. 14, the passivation layer PL may be formed on the stacked insulating structure 110 across the main chip region MC and the scribe lane region SL.

In the main chip region MC, a region exposed by the passivation layer PL may include the plurality of bump pads 141P. For example, the portion of the redistribution structure 141 exposed by the passivation layer PL may be referred to as the plurality of bump pads 141P.

In the scribe lane region SL, the passivation layer PL may be formed to expose the plurality of heat transfer pads 143.

Referring to FIG. 15, the die sawing process may be performed by using the sawing blade SB in the second region R2 of the scribe lane region SL.

By performing the die sawing process along the second region R2 of the scribe lane region SL, the semiconductor chips 100 may be physically separated from each other. The semiconductor substrate 101 and various types of material layers formed on the semiconductor substrate 101 are cut by the die sawing process using the sawing blade SB, thereby being separated into the plurality of semiconductor chips 100.

In this case, the crack CR starting at the point at which the sawing blade SB and the stacked insulating structure 110 or the sawing blade SB and the semiconductor substrate 101 come into contact and propagating toward the main chip region MC may be extinguished/terminated upon encountering the through structure 130.

Accordingly, the through structure 130 formed integrally from the uppermost surface of the stacked insulating structure 110 to the lowermost surface of the semiconductor substrate 101 may prevent the crack CR from propagating toward the main chip region MC.

Referring again to FIG. 3, the semiconductor chip 100 may be manufactured by the manufacturing processes described above.

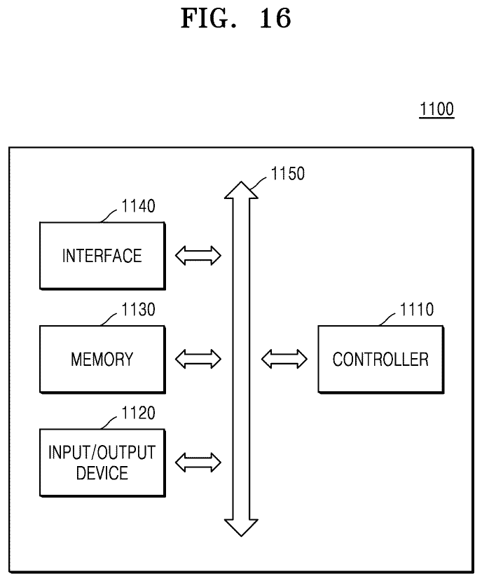

FIG. 16 is a block diagram illustrating an example of a system 1100 of a semiconductor package.

Referring to FIG. 16, the system 1100 includes a controller 1110, an input/output device 1120, memory 1130, an interface 1140, and a bus 1150.

The system 1100 may include a mobile system or a system transmitting or receiving information. In some implementations, the mobile system may include a portable computer, a web tablet, a mobile phone, a digital music player, or a memory card.

The controller 1110 for controlling an execution program in the system 1100 may include a microprocessor, a digital signal processor, a microcontroller, or a similar device.

The input/output device 1120 may be used to input or output data of the system 1100. The system 1100 may be connected to an external device, for example, a personal computer or a network, by using the input/output device 1120, and may exchange data with the external device. The input/output device 1120 may include, for example, a touch pad, a keyboard, or a display device.

The memory 1130 may store data for the operation of the controller 1110 or may store data processed by the controller 1110. The memory 1130 may include any one of the semiconductor chips 100, 100A, 100B, and 100C described above and their modified implementations.

The interface 1140 may include a data transmission path between the system 1100 and the external device. The controller 1110, the input/output device 1120, the memory 1130, and the interface 1140 may communicate with one another through the bus 1150.

In this disclosure, a first element that is “exposed by” a second element may be covered by other element(s), without departing from the scope of this disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A semiconductor chip comprising:
a main chip region;
a residual scribe lane region surrounding the main chip region;
a semiconductor substrate spanning the main chip region and the residual scribe lane region;
a stacked insulating structure on the semiconductor substrate;
a plurality of bump pads in the main chip region;
a passivation layer on the stacked insulating structure, wherein the plurality of bump pads are exposed through first openings, respectively, in the passivation layer;
a heat transfer pad in the residual scribe lane region, wherein the heat transfer pad is exposed through a second opening in the passivation layer; and
a through structure in the residual scribe lane region, wherein the through structure extends through the stacked insulating structure and the semiconductor substrate in a vertical direction from a bottom surface of the heat transfer pad to a lowermost surface of the semiconductor substrate,
wherein, in a plan view, the through structure surrounds the main chip region, and
wherein the through structure comprises an integrally formed body that extends from the bottom surface of the heat transfer pad to the lowermost surface of the semiconductor substrate.

2. The semiconductor chip of claim 1, wherein the heat transfer pad has a trapezoidal shape, wherein a horizontal width of the heat transfer pad increases toward the semiconductor substrate in the vertical direction,
wherein the through structure has a tapered shape, and wherein a horizontal width of the through structure decreases toward the lowermost surface of the semiconductor substrate in the vertical direction.

3. The semiconductor chip of claim 2, wherein a greatest horizontal width of the heat transfer pad is greater than a greatest horizontal width of the through structure, and
wherein the bottom surface of the heat transfer pad covers an entire top surface of the through structure.

4. The semiconductor chip of claim 1, wherein a vertical level of the plurality of bump pads is substantially the same as a vertical level of the heat transfer pad, and
wherein a material constituting the plurality of bump pads is substantially the same as a material constituting the heat transfer pad.

5. The semiconductor chip of claim 4, wherein a material constituting the through structure is different from a material constituting the heat transfer pad.

6. The semiconductor chip of claim 1, comprising a through insulating liner surrounding the through structure.

7. The semiconductor chip of claim 6, wherein the through insulating liner extends through the stacked insulating structure and the semiconductor substrate in the vertical direction from the bottom surface of the heat transfer pad to the lowermost surface of the semiconductor substrate.

8. The semiconductor chip of claim 1, wherein, in a plan view, the through structure comprises a continuous pattern completely surrounding the main chip region.

9. The semiconductor chip of claim 1, wherein, in a plan view, the through structure comprises a plurality of continuous patterns, wherein each of the plurality of continuous patterns completely surrounds the main chip region.

10. The semiconductor chip of claim 1, wherein, in a plan view, the through structure comprises a plurality of discontinuous lines, wherein the plurality of discontinuous lines together completely surround the main chip region.

11. A semiconductor chip comprising:
a semiconductor substrate;
a plurality of transistors on the semiconductor substrate in a main chip region of the semiconductor chip;
a through structure in a residual scribe lane region of the semiconductor chip, wherein the residual scribe lane region surrounds the main chip region, and wherein the through structure extends through the semiconductor substrate in a vertical direction; and
a heat transfer pad in the residual scribe lane region, wherein the heat transfer pad is on the through structure, and
wherein the through structure comprises an integrally formed body that extends from a bottom surface of the heat transfer pad to a lowermost surface of the semiconductor substrate, and
wherein the through structure is configured to transfer heat generated in the main chip region away from the semiconductor chip.

12. The semiconductor chip of claim 11, wherein an uppermost surface of the heat transfer pad is exposed to an outside of the semiconductor chip, and
wherein a lowermost surface of the through structure is exposed to the outside of the semiconductor chip.

13. The semiconductor chip of claim 12, wherein a vertical level of the lowermost surface of the through structure is substantially the same as a vertical level of the lowermost surface of the semiconductor substrate.

14. The semiconductor chip of claim 11, comprising a plurality of bump pads at substantially a same vertical level as the heat transfer pad, wherein the plurality of bump pads are in the main chip region,
wherein the plurality of bump pads are composed of substantially a same material as the heat transfer pad,
wherein the plurality of bump pads are electrically connected to the plurality of transistors, and
wherein the heat transfer pad is electrically insulated from the plurality of transistors.

15. The semiconductor chip of claim 11, wherein the heat transfer pad has a trapezoidal shape, and
wherein the through structure has an inverted trapezoidal shape.

16. A semiconductor package comprising:
a package substrate;
a semiconductor chip stack mounted on the package substrate and including a plurality of semiconductor chips stacked in a vertical direction, wherein each semiconductor chip comprises a main chip region and a residual scribe lane region surrounding the main chip region; and
a molding member surrounding the semiconductor chip stack, wherein each semiconductor chip of the plurality of semiconductor chips comprises:
a semiconductor substrate spanning the main chip region of the semiconductor chip and the residual scribe lane region of the semiconductor chip,
a stacked insulating structure on the semiconductor substrate,
a passivation layer on the stacked insulating structure,
a plurality of bump pads in the main chip region of the semiconductor chip, wherein the plurality of bump pads are exposed through first openings, respectively, in the passivation layer,
a heat transfer pad in the residual scribe lane region of the semiconductor chip, wherein the heat transfer pad is through a second opening in the passivation layer, and
a through structure in the residual scribe lane region of the semiconductor chip, wherein the through structure extends through the stacked insulating structure and the semiconductor substrate in the vertical direction from a bottom surface of the heat transfer pad to a lowermost surface of the semiconductor substrate, and
wherein, in the semiconductor chip stack, the plurality of semiconductor chips are mounted to one another through:
the plurality of bump pads of the plurality of semiconductor chips, and
a plurality of solder bumps on the heat transfer pads of the plurality of semiconductor chips.

17. The semiconductor package of claim 16, wherein, in a plan view, the through structure surrounds the main chip region,
wherein the through structure comprises an integrally formed body that extends from the bottom surface of the heat transfer pad to the lowermost surface of the semiconductor substrate,
wherein the through structure has a tapered shape, wherein a horizontal width of the through structure increases toward the package substrate in the vertical direction,
wherein the heat transfer pad has an inverted trapezoidal shape, and wherein a horizontal width of the heat transfer pad decreases toward the package substrate in the vertical direction.

18. The semiconductor package of claim 16, comprising a second plurality of solder bumps arranged on the plurality of bump pads, wherein the second plurality of solder bumps electrically connect semiconductor devices of the plurality of semiconductor chips to one another and electrically connect the semiconductor chip stack to the package substrate, and
wherein the plurality of solder bumps on the heat transfer pads of the plurality of semiconductor chips are electrically insulated from the semiconductor devices of the plurality of semiconductor chips.

19. The semiconductor package of claim 16, wherein, in a plan view, the through structure comprises a continuous structure surrounding the main chip region, and the heat transfer pad comprises a continuous pad overlapping the through structure along the vertical direction.

20. The semiconductor package of claim 16, wherein, in a plan view, the through structure comprises a continuous structure surrounding the main chip region, and the heat transfer pad comprises a plurality of discontinuous pads overlapping the through structure along the vertical direction.
